(19) United States
(12) Patent Application Publication
(10) Pub. No.: US 2018/0298487 A1
(43) Pub. Date: Oct. 18, 2018

(54) CRUCIBLE, EVAPORATION DEVICE AND EVAPORATION APPARATUS

(71) Applicant: BOE TECHNOLOGY GROUP CO., LTD., Beijing (CN)

(72) Inventor: Yongfeng ZHANG, Beijing (CN)

(21) Appl. No.: 15/580,123

(22) PCT Filed: Jun. 21, 2017
(86) PCT No.: PCT/CN2017/089355

§ 371 Date: Dec. 6, 2017

(30) Foreign Application Priority Data
Sep. 27, 2016 (CN) 201610850525.3

(51) Int. Cl. C23C 14/24

(52) U.S. Cl. CPC C23C 14/243

(57) ABSTRACT

A crucible, an evaporation device and an evaporation system are provided in embodiments of the disclosure, the crucible comprising a crucible body, which defines therein an accommodation chamber which is configured to accommodate a material to be heated, and the crucible further comprises a collector, which is located in the accommodation chamber and configured to collect impurities produced during an evaporation in the crucible and opens towards an upper portion of the accommodation chamber facing away from a bottom of the crucible body.

### CROSS-REFERENCE TO RELATED INVENTION

This application is a Section 371 National Stage application of International Application No. PCT/CN2017/089355, filed on 21 Jun. 2017, which has not yet published, and claims priority to Chinese Patent Application Invention No. 201610850525.3 filed on Sep. 27, 2016 in the State Intellectual Property Office of China, the disclosures of which are incorporated herein by reference.

### BACKGROUND OF THE DISCLOSURE

### Field of the Disclosure

Embodiments of the present disclosure relate to the technical field of evaporation, and in particular, to a crucible, an evaporation device and an evaporation system.

### Description of the Related Art

Nowadays, an evaporation process is widely used in production of plating films of electronic devices. In the evaporation process, a raw material is placed within an evaporation device, e.g., a crucible, and is then heated to a certain temperature by a heating source and is in turn evaporated or sublimated so as to deposit onto a surface of a substrate on which the plating film is to be formed, such that the plating of the film is completed.

In a preparation of an OLED device such as an OLED display panel and the like, it is required to use active metal materials such as Mg, Al and the like each having a relatively low work function so as to prepare a cathode. In order to implement a match of energy levels between the cathode and a material for an electron injection layer and to enhance an electrical conductivity property of the cathode, a mixture between Mg and Al is typically adopted, e.g., with a mixture ratio of 9:1 therebetween, so as to obtain a balance among properties in various aspects. However, since the metal material Mg is active, it is inevitable in a long run period of the evaporation that, Mg may react with O₂ and N₂ left in a chamber for evaporation (i.e., evaporation chamber hereinafter) so as to form impurities pieces of magnesian lime or ash. The impurities accumulate more and more over time and a portion thereof moves with evaporated Mg radicals to a surface of a glass substrate so as to be attached thereto, resulting in fouling or contamination on the substrate of the formed display panel, and in turn display defects of the display panel.

### SUMMARY OF THE DISCLOSURE

The embodiments of the present disclosure have been made to overcome or alleviate at least one aspect of the above mentioned disadvantages and/or shortcomings in the prior art, by providing a crucible, an evaporation device and an evaporation system, which are capable of solving a problem that impurities formed in the evaporation may pollute the evaporation chamber and may also move with the evaporated material(s) onto the substrate to be processed by evaporation.

Following technical solutions are adopted in exemplary embodiments of the invention for achieving the above desired technical purposes.

According to an aspect of the exemplary embodiment of the present disclosure, there is provided a crucible, comprising a crucible body, which defines therein an accommodation chamber which is configured to accommodate a material to be heated, and the crucible further comprises: a collector, which is located in the accommodation chamber and configured to collect impurities produced during an evaporation in the crucible and opens towards an upper portion of the accommodation chamber facing away from a bottom of the crucible body.

According to an embodiment of the disclosure, the crucible further comprises a crucible cover, which is disposed above the accommodation chamber and provided with at least one hole penetrating therethrough, with an area of a top surface of the crucible cover located at a side thereof facing away from the accommodation chamber being less than that of a bottom surface thereof located at a side of the crucible cover located at another side thereof facing towards the accommodation chamber.

According to an embodiment of the disclosure, each of the top surface and the bottom surface is of a round shape, and a diameter of the top surface is in a range of about 0.5˜2 mm while a diameter of the bottom surface is in a range of about 2˜4 mm

According to an embodiment of the disclosure, the hole is in a form of an isosceles trapezoid shape, at a longitudinal section thereof on a plane perpendicular to the top surface.

According to an embodiment of the disclosure, the crucible further comprises a thermal conductive plate, which is provided in the accommodation chamber on a bottom portion thereof.

According to an embodiment of the disclosure, the thermal conductive plate is shaped to be in a form of a honeycomb shape, at a cross section thereof on a plane parallel to the top surface.

According to an embodiment of the disclosure, the collector is shaped in a form of one of a funnel-shape, an ellipsoid-shape and a plate-shape.

According to an embodiment of the disclosure, the collector is shaped to be concave and opens to face away from the bottom wall.

According to another aspect of the exemplary embodiment of the present disclosure, there is provided an evaporation device, comprising a heating source and the crucible as above, and the heating source is configured to heat the crucible.

According to an embodiment of the disclosure, the heating source is provided on a side surface of the crucible, and comprises a first heating portion and a second heating portion arranged in a direction extending from a bottom of the crucible to the crucible cover, the second heating portion being disposed above the first heating portion, and the second heating portion is configured to provide a second heating temperature higher than a first heating temperature provided by the first heating portion.

According to still another aspect of the exemplary embodiment of the present disclosure, there is provided an evaporation system comprising the evaporation device as above.

### BRIEF DESCRIPTION OF THE DRAWINGS

The above and other features and advantages of the present disclosure will become more apparent and a more comprehensive understanding of the present disclosure can be obtained, by describing in detail exemplary embodiments thereof with reference to the accompanying drawings, in which:

FIG. 1 illustrates a schematic view of a crucible according to an embodiment of the disclosure;

FIG. 2(a) illustrates a schematic view of a crucible according to an embodiment of the disclosure;

FIG. 2(b) illustrates a partially enlarged schematic view of a crucible cover according to an embodiment of the disclosure;

FIG. 3 illustrates a schematic view of a crucible according to an embodiment of the disclosure;

FIG. 4 illustrates a schematic top view of a thermal conductive plate according to an embodiment of the disclosure;

FIG. 5(a) illustrates a schematic view of a crucible according to an embodiment of the disclosure;

FIG. 5(b) illustrates a schematic view of a crucible according to another embodiment of the disclosure;

FIG. 6 illustrates a schematic view of an evaporation device according to an embodiment of the disclosure; and

FIG. 7 illustrates a schematic view of an evaporation device according to an embodiment of the disclosure.

### DETAILED DESCRIPTION OF PREFERRED EMBODIMENTS OF THE INVENTION

Exemplary embodiments of the present disclosure will be described hereinafter in detail with reference to the attached drawings, wherein the like reference numerals refer to the like elements. The present disclosure may, however, be embodied in many different forms, and thus the detailed description of the embodiment of the disclosure in view of attached drawings should not be construed as being limited to the embodiment set forth herein; rather, these embodiments are provided so that the present disclosure will be thorough and complete, and will fully convey the general concept of the disclosure to those skilled in the art.

In the following detailed description, for purposes of explanation, numerous specific details are set forth in order to provide a thorough understanding of the disclosed embodiments. It will be apparent, however, that one or more embodiments may be practiced without these specific details. In other instances, well-known structures and devices are schematically shown in order to simplify the drawing.

Respective dimension and shape of each component in the drawings are only intended to exemplarily illustrate the contents of the disclosure, rather than to demonstrate the practical dimension or proportion of components of the crucible, the evaporation device and the evaporation system.

When introducing elements and embodiments of the present disclosure, a singular form of terms used in the present text and the attached claims also includes a plural form thereof, unless being explicitly specified in the context; and vice versa. Therefore, upon mentioning the singular form thereof, it normally means including the plural form of the corresponding term. Terms “including”, “comprising”, “containing” and “having” are intended to be inclusive, and mean the possibility of existence of other element than the listed elements herein.

For sake of brevity of description below, as the directions indicated in the drawings, terms “upper”, “lower”, “left”, “right”, “perpendicular”, “horizontal”, “top”, “bottom” as well as derivatives thereof are involved in the present disclosure. Terms “coated . . . above”, “on a top of”, “located onto . . . ” or “positioned on a top of . . . ” means that a first element of a first structure is present on a second element of a second structure, for example. There is also possible to have an intermediate element (for example an interface structure) between the first element and the second element. Term “contact” means connecting the first element of the first structure and the second element of the second structure, while other elements can or cannot be present at an interface of the two elements.

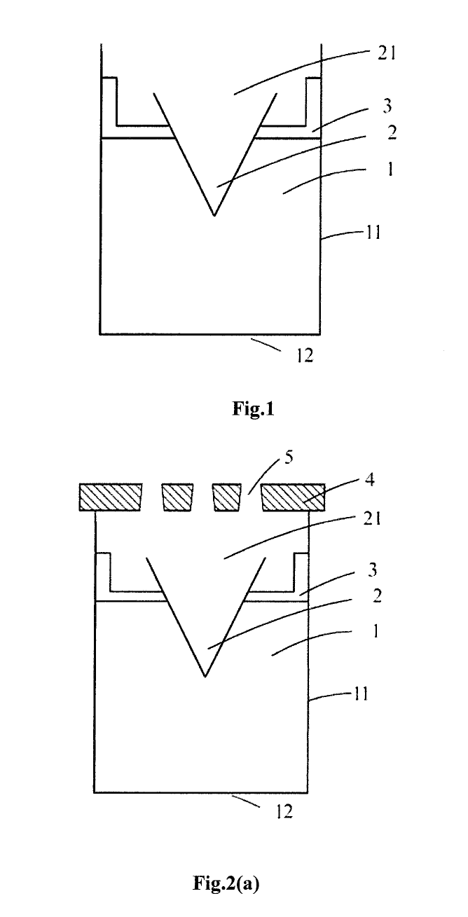

FIG. 1 illustrates a schematic view of a crucible according to an embodiment of the disclosure. As illustrated in FIG. 1, according to a general technical concept of the present disclosure, there is provided a crucible, comprising a crucible body, which is for example provided with a side wall 11 and a bottom wall 12 thereof and defines therein an accommodation chamber 1 which is configured to accommodate a material to be heated, e.g., by connection and cooperation of the side wall 11 and the bottom wall 12 so as to delimit the accommodation chamber surrounded thereby. And as seen from FIG. 1, the crucible also comprises a collector 2 which is located in the accommodation chamber and configured to collect impurities produced during an evaporation in the crucible, and has an opening 21 facing towards an upper portion of the accommodation chamber 1 facing away from a bottom of the crucible body. As illustrated, the collector is for example in a form of an inverted cone which has a relative wide bottom thereof directing and opening upwards, i.e., the collector is shaped to be depressed. And by way of example. Optionally, the crucible further comprises a support device 3 configured to support the collector 2. The support device 3 is for example an latch groove, especially which is provided with a central opening thereof as illustrated such that the collector may penetrate therethrough partially and be restricted in place in the support device 3. Here the support device 3 which functions as a component independently of the collector 2 is taken as an example. The side wall, the bottom wall, the collector and the support device cooperate with one another to define collectively an accommodation chamber which is configured to accommodate a material to be heated. It may be understood that, the collector 2 is for example self-supported in the crucible without any dedicated support device 3. And by way of example, the collector 2 is shaped to be concave and opens to face away from the bottom wall 12. For example, the collector 2 is mounted at an edge thereof directly onto the crucible therein and seals the crucible so as to define collectively the accommodation chamber therebetween. Size and specific position of the collector may be preset as required practically, without any restriction herein.

By providing the collector which is disposed in the accommodation chamber of the crucible and opens to face towards a top portion of the accommodation chamber, then the impurities produced in the evaporation may be collected by the collector so as to decrease contamination of the accommodation chamber such as a vacuum evaporation chamber and the like and to reduce probability of a deposition of the impurities onto the substrate, resulting in a significant reduction of probability of abnormity caused by the deposition.

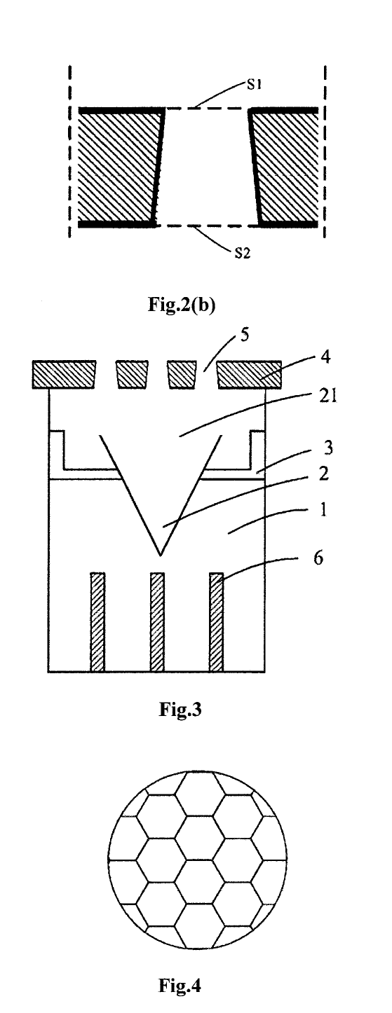

FIG. 2(a) illustrates a schematic view of a crucible according to an embodiment of the disclosure. As illustrated in FIG. 2(a), the crucible further comprises a crucible cover 4 which is disposed above the accommodation chamber (e.g., at a side of the collector facing away from the accommodation chamber), connected with the side wall, and provided with at least one hole 5 penetrating therethrough. Herein, a portion of the hole on a surface of the crucible cover at a side thereof facing away from the accommodation chamber is defined as a “top surface” or “first opening”, while another portion of the hole on a surface of the crucible cover at a side thereof facing towards the accommodation chamber is defined as a “bottom surface” or “second opening”. It may be seen that, an area of the top surface opening of the hole 5 is less than that of the bottom surface or the second opening of the hole 5. In other words, the hole 5 is an aperture which is slimmer in its upper portion and broader in its lower portion so as to flare towards the accommodation chamber.

FIG. 2(b) illustrates a partially enlarged schematic view of a crucible cover according to an embodiment of the disclosure. It may be seen more clearly from FIG. 2(b) that, the area S1 of the top surface or the first opening of the hole 5 is less than the area S2 of the bottom surface or the second opening of the hole 5.

By the hole provided in the crucible cover as such, it may facilitate stabilization of both a flow of a vapor of the evaporated material (e.g., Mg) and a movement direction thereof, such that a relatively larger proportion of the evaporated material may escape therethrough, and an escape of solid impurities (e.g., comprising magnesium oxide, and/or magnesian lime/ash of magnesium oxide) through the hole 5 from the crucible, which are carried with the flow of the vapor upwards, may be restricted correspondingly.

In an embodiment, upon consideration of both dimensions of the impurities and the evaporated material, in order to restrict both escape of the solid impurities and to facilitate escape of gaseous evaporated material in an improved manner, e.g., the hole may be provided to have specific dimensions. By way of example, each of the top surface or the first opening and the bottom surface or the second opening of the hole is set to be of a round shape, and a first diameter of the top surface or the first opening is set to be in a range of about 0.5˜2 mm while a second diameter of the bottom surfaceor the second opening is set to be in a range of about 2˜4 mm

In an example, the hole is in a form of an isosceles trapezoid shape, at a longitudinal section thereof on a plane perpendicular to the top surface. The hole may for example be in a form of a truncated conical shape. Such a design thereof may not only restrict outflowing escape of an undesired material (e.g., impurities pieces of magnesian lime or ash) with the flow of vapor, but also correct movement directions of molecules of desired evaporated material (e.g., Mg radicals) by the shape, size and opening direction of the hole such that the movement directions of the molecules of the evaporated material are essentially vertically upwards as far as possible.

FIG. 3 illustrates a schematic view of a crucible according to an embodiment of the disclosure. As illustrated in FIG. 3, the crucible further comprises a thermal conductive plate 6 which is provided in the accommodation chamber on a bottom portion thereof and extends towards the crucible cover. By provision of the thermal conductive plate, an contact area between the crucible and the vapor of the evaporated material such as Mg and the like are increased, such that the vapor of the evaporated material is heated more uniformly so as to stabilize evaporation rate of the evaporated material and to balance evaporation rate throughout the accommodation chamber for facilitating a better evaporation effect. The thermal conductive plate may for example form an integral structure with the bottom of the crucible.

FIG. 4 illustrates a schematic top view of a thermal conductive plate according to an embodiment of the disclosure. As illustrated in FIG. 4, the thermal conductive plate in the crucible extends from the bottom up towards the crucible cover for example, and is configured to be in a form of a honeycomb shape, at a cross section thereof on a plane parallel to the top surface. It should be noticed that, it is only an exemplary embodiment that the honeycomb shape of the thermal conductive plate as illustrated in FIG. 4 comprises a plurality of hexagons, rather than a limitation on the honeycomb shape of the thermal conductive plate. For example, the specific honeycomb shape of the thermal conductive plate may be provided as required practically. By way of example, the honeycomb shape may comprise a plurality of round shapes, quadrangular shapes, pentagonal shapes, and heptagonal shapes and the like.

Specific shape of the collector may not be limited to the funnel shape as illustrated, and may alternatively comprise an ellipsoid-shape, a plate-shape or the like. The specific shape of the collector may be provided to be any expected shape as required practically.

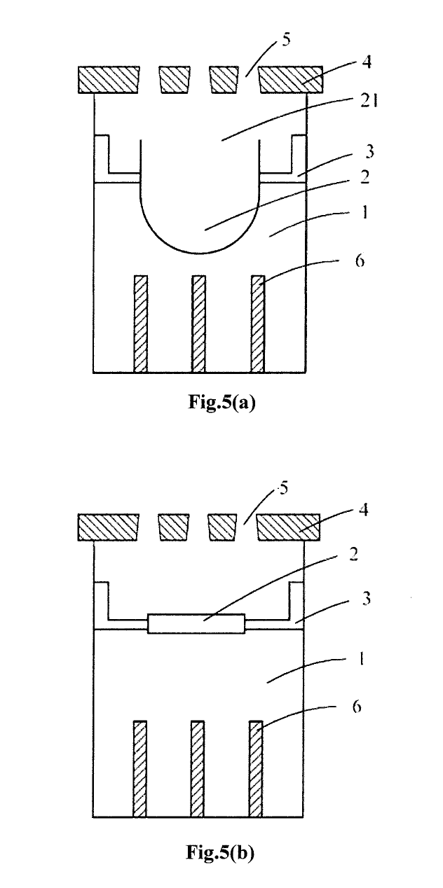

FIG. 5(a) illustrates a schematic view of a crucible according to an embodiment of the disclosure; and as illustrated in FIG. 5(a), a collector 2 which is shaped in a form of a concave partial ellipsoid shape is taken as an example It should also be understood that, it is not necessary to provide the support device 3 which is configured to support the collector 2 within the crucible. The collector may alternatively be placed in the crucible, e.g., mounted at an edge thereof directly onto and within the crucible, and seals the crucible so as to cooperate with the crucible to define collectively the accommodation chamber therebetween, without any dedicated support device.

FIG. 5(b) illustrates a schematic view of a crucible according to another embodiment of the disclosure; and as illustrated in FIG. 5(b), a collector 2 which is shaped in a form of a plate shape is taken as an example, with a groove opening upwards which is positioned at a center of the collector. The plate shape as illustrated in FIG. 5(b) is merely exemplary; in other words, the plate shape may not be limited to a planar plate shape, and a slotted or grooved structure which has an opening therein also belongs to the “plate shape” herein.

In another aspect of the embodiments of the disclosure, there is also provided an evaporation device, comprising the crucible as above and a heating source which is configured to heat the crucible.

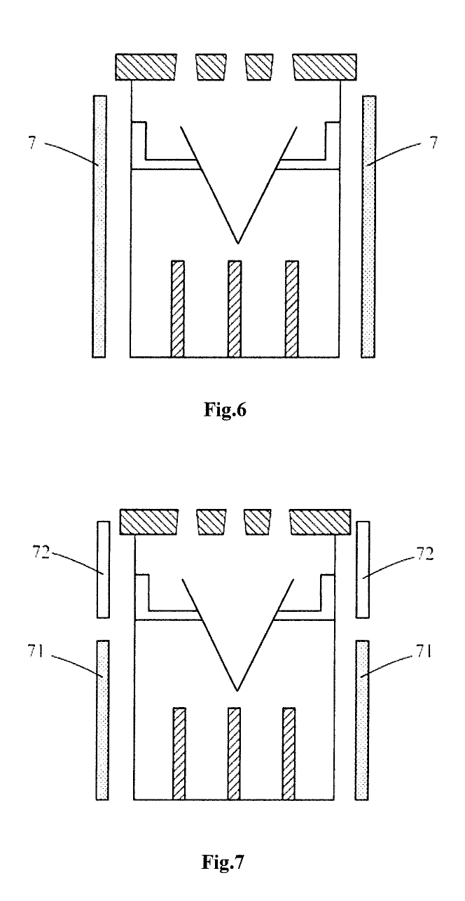

FIG. 6 illustrates a schematic view of an evaporation device according to an embodiment of the disclosure. As illustrated in FIG. 6, the evaporation device comprises the heating source 7 and the crucible as above. The heating source 7 as illustrated, which is provided substantially parallel to or slightly at an angle to the side wall of the crucible, is configured to heat the crucible.

FIG. 7 illustrates a schematic view of an evaporation device according to an embodiment of the disclosure. As illustrated in FIG. 7, the heating source of the evaporation device is provided on a side surface or side surfaces of the crucible, and comprises a first heating portion 71 and a second heating portion 72 spaced apart from each other in a direction extending from the bottom wall of the crucible to the crucible cover, the second heating portion 72 being disposed above and essentially aligned with the first heating portion 71. And the second heating portion is configured to provide a second heating temperature higher than a first heating temperature provided by the first heating portion. By the first heating portion and the second heating portion as provided, the flow of vapor of the evaporated material is heated incrementally in two stages, at both sides of the collector when it flows from the bottom of the crucible upwards, such that the flow of vapor of the evaporated material which has flowed upwards and escaped out of the accommodation chamber through the hole 5 is heated to an elevated temperature which is essentially in balance with that of the crucible cover, so as to avoid deposition of the molecules of the evaporated material (e.g., Mg radicals) having an excessively high temperature once got in touch with the crucible cover having a relatively lower temperature, and in turn to avoid any blockage of the hole thus caused.

In practical operation, by way of example, the second heating temperature of the second heating portion is set to be higher than the first heating temperature of the first heating portion, with a difference therebetween being in a range of about 50-100° C., so as to facilitate the escape of the evaporated material from the accommodation chamber. By way of example, as to the evaporated material comprising Mg, the first heating temperature of the first heating portion is set to be in a range of about 450-500° C., and the second heating temperature of the second heating portion is set to be in a range of about 500-550° C.

In still another aspect of the embodiments of the disclosure, there is also provided an evaporation system, comprising the evaporation device as above.

It should be appreciated for those skilled in this art that the above embodiments are intended to be illustrated, and not restrictive. For example, many modifications may be made to the above embodiments by those skilled in this art, and various features described in different embodiments may be freely combined with each other without conflicting in configuration or principle.

Although the disclosure is described in view of the attached drawings, the embodiments disclosed in the drawings are only intended to illustrate the preferable embodiment of the present disclosure exemplarily, and should not be deemed as a restriction thereof.

Although several exemplary embodiments of the general concept of the present disclosure have been shown and described, it would be appreciated by those skilled in the art that various changes or modifications may be made in these embodiments without departing from the principles and spirit of the disclosure and lie within the scope of present application, which scope is defined in the claims and their equivalents.

As used herein, an element recited in the singular and proceeded with the word “a” or “an” should be understood as not excluding plural of said elements or steps, unless such exclusion is explicitly stated. Furthermore, references to “one embodiment” of the present disclosure are not intended to be interpreted as excluding the existence of additional embodiments that also incorporate the recited features. Moreover, unless explicitly stated to the contrary, embodiments “comprising” or “having” an element or a plurality of elements having a particular property may include additional such elements not having that property.

1. A crucible, comprising a crucible body, which defines therein an accommodation chamber which is configured to accommodate a material to be heated,
wherein the crucible further comprises:
a collector, which is located in the accommodation chamber and configured to collect impurities produced during an evaporation in the crucible and opens towards an upper portion of the accommodation chamber facing away from a bottom of the crucible body.

2. The crucible according to claim 1, further comprising a crucible cover which is disposed above the accommodation chamber and provided with at least one hole penetrating therethrough, with an area of a top surface of the crucible cover located at a side thereof facing away from the accommodation chamber being less than that of a bottom surface thereof located at a side of the crucible cover located at another side thereof facing towards the accommodation chamber.

3. The crucible according to claim 2, wherein each of the top surface and the bottom surface is of a round shape, and
wherein a diameter of the top surface is in a range of about 0.5˜2 mm while a diameter of the bottom surface is in a range of about 2˜4 mm.

4. The crucible according to claim 3, wherein the hole is in a form of an isosceles trapezoid shape, at a longitudinal section thereof on a plane perpendicular to the top surface.

5. The crucible according to claim 2, further comprising a thermal conductive plate, which is provided in the accommodation chamber on a bottom portion thereof.

6. The crucible according to claim 5, wherein the thermal conductive plate is shaped to be in a form of a honeycomb shape, at a cross section thereof on a plane parallel to the top surface.

7. The crucible according to claim 1, wherein the collector is shaped in a form of one of a funnel-shape, an ellipsoid-shape and a plate-shape.

8. An evaporation device, comprising a heating source and the crucible according to claim 1, wherein the heating source is configured to heat the crucible.

9. The evaporation device according to claim 8, wherein the heating source is provided on a side surface of the crucible, and comprises a first heating portion and a second heating portion arranged in a direction extending from a bottom of the crucible to the crucible cover, the second heating portion being disposed above the first heating portion, and
wherein the second heating portion is configured to provide a second heating temperature higher than a first heating temperature provided by the first heating portion.

10. An evaporation system comprising the evaporation device according to claim 8.
